(19) United States
(12) Patent Application Publication
(10) Pub. No.: US 2025/0231253 A1
(43) Pub. Date: Jul. 17, 2025

(54) MONITORING SECONDARY POWER SOURCES

(71) Applicant: Samsung Electronics Co., Ltd., Suwon-si (KR)

(72) Inventors: Woosung Lee, Suwon-si (KR); Yuhyun Kim, Suwon-si (KR); Hyunglae Eun, Suwon-si (KR)

(21) Appl. No.: 18/937,995

(22) Filed: Nov. 5, 2024

(30) Foreign Application Priority Data
Jan. 17, 2024 (KR) 10-2024-0007442

(51) Int. Cl. G01R 31/40; G11C 16/04; G11C 16/30; H02J 7/00; H02J 7/34

(52) U.S. Cl. CPC G01R 31/40; H02J 7/0047; H02J 7/00712; H02J 7/345; G11C 16/0483; G11C 16/30; H02J 2207/50

(57) ABSTRACT

A storage device includes a secondary power source, a charging circuit, a main system and a monitoring circuit. The secondary power source includes a capacitor, is charged based on a charging voltage, and generates an internal power supply voltage. The charging circuit generates the charging voltage based on an external power supply voltage. The monitoring circuit includes a first path, a second path and a control circuit. The first path is formed separately from a leakage path of the capacitor. The second path is formed separately from the leakage path and the first path. The control circuit calculates the leakage current while the second path is activated and deactivated, calculates the capacitance using the leakage current, and determines whether a defect has occurred in the secondary power source based on at least one of the leakage current and the capacitance.

### CROSS-REFERENCE TO RELATED APPLICATION

This application claims priority under 35 USC § 119 to Korean Patent Application No. 10-2024-0007442 filed on Jan. 17, 2024 in the Korean Intellectual Property Office, the contents of which are herein incorporated by reference in their entirety.

### BACKGROUND

Certain types of data storage devices include one or more semiconductor memory devices. Examples of such data storage devices include solid state drives (SSDs). These types of data storage devices may have various design and/or performance advantages over hard disk drives (HDDs). Examples of potential advantages include the absence of moving mechanical parts, higher data access speeds, stability, durability, and/or low power consumption. Recently, various systems, such as laptop computers, cars, airplanes, drones, etc., have adopted the SSDs for data storage.

Storage devices including a storage controller, a volatile memory and nonvolatile memories typically operate by receiving externally-supplied power. During operation of a storage device, a sudden power-off (SPO) event where power is suddenly interrupted may occur. A storage controller stores data using a volatile memory, and thus data stored in the volatile memory may be lost, or an ongoing operation in a nonvolatile memory (for example, an erase operation, a write operation, or the like) may not be completed when an SPO event occurs. A storage device may complete an ongoing operation using a secondary power source, and may perform a data backup operation.

### SUMMARY

Some implementations according to the present disclosure provide storage devices including a monitoring circuit capable of efficiently detecting a defect or failure on a secondary power source included in the storage device.

Some implementations according to the present disclosure provide methods of monitoring a secondary power source, e.g., methods performed by disclosed monitoring circuist.

According to some implementations, a storage device includes a secondary power source, a charging circuit, a main system and a monitoring circuit. The secondary power source includes at least one capacitor, is charged based on a charging voltage, and generates an internal power supply voltage. The charging circuit generates the charging voltage based on an external power supply voltage. The main system operates based on the external power supply voltage or the internal power supply voltage. The monitoring circuit is connected to the secondary power source, and detects whether the secondary power source is defective by measuring a capacitance of the at least one capacitor and a leakage current of the at least one capacitor. The monitoring circuit includes a first path, a second path and a control circuit. The first path is formed separately from a leakage path of the at least one capacitor. The leakage current flows through the leakage path. The second path is formed separately from the leakage path and the first path. The control circuit controls activation and deactivation of the second path, calculates the leakage current while the second path is activated and deactivated, calculates the capacitance using the leakage current, and determines whether a defect has occured in the secondary power source based on at least one of the leakage current and the capacitance.

According to some implementations, in a method of monitoring a secondary power source included in a storage device, the secondary power source includes at least one capacitor and generates an internal power supply voltage based on a charging voltage. A leakage current of the at least one capacitor is measured using a monitoring circuit connected to the secondary power source. A capacitance of the at least one capacitor is measured using the monitoring circuit and the leakage current. It is determined based on at least one of the leakage current and the capacitance whether a defect has occured in the secondary power source. The monitoring circuit includes a first path and a second path. The first path is formed separately from a leakage path of the at least one capacitor. The leakage current flows through the leakage path. The second path is formed separately from the leakage path and the first path. The leakage current is calculated while the second path is activated and deactivated.

According to some implementations, a storage device includes a secondary power source, a charging circuit, a main system and a monitoring circuit. The secondary power source generates an internal power supply voltage based on a charging voltage, and includes a capacitor and a leakage path. The capacitor is connected between the charging voltage and a ground voltage. The leakage path is a path through which a leakage current of the capacitor flows. The charging circuit generates the charging voltage based on an external power supply voltage. The main system operates based on the external power supply voltage or the internal power supply voltage. The monitoring circuit is connected to the secondary power source, and detects whether the secondary power source is defective by measuring a capacitance of the capacitor and the leakage current of the capacitor. The monitoring circuit includes a first path, a second path, a measurer, a calculator and a determinator. The first path includes a first resistor that is connected between the charging voltage and the ground voltage. The second path includes a second resistor and a leakage switch that are connected in series between the charging voltage and the ground voltage. The measurer measures a first time interval during which a voltage level of a capacitor voltage of the capacitor decreases from a first voltage level to a second voltage level lower than the first voltage level while the leakage switch is turned off to deactivate the second path, and measures a second time interval during which the voltage level of the capacitor voltage decreases from the first voltage level to the second voltage level while the leakage switch is turned on to activate the second path. The calculator calculates the leakage current based on the first time interval and the second time interval, and calculates the capacitance based on the leakage current. The determinator determines that a defect has occured in the secondary power source when the leakage current is greater than or equal to a reference current, and determines that the defect has occured in the secondary power source when the capacitance is less than or equal to a reference capacitance.

In some implementations, in a storage device and a method of monitoring a secondary power source, a first path and a second path may be formed separately from a leakage path. The leakage current may be calculated by performing two tests while the second path is activated and deactivated, and it may be determined based on the leakage current whether the defect has occurred in the secondary power source. In some implementations, the capacitance of the secondary power source may be calculated using the leakage current, and it may be determined based on the capacitance whether the defect has occurred in the secondary power source. Accordingly, defects in the secondary power source may be efficiently detected, and operating performance and/or efficiency of the storage device may be prevented from being degraded or deteriorated while maintaining target operation of the storage device.

### BRIEF DESCRIPTION OF THE DRAWINGS

Implementations according to the present disclosure will be more clearly understood from the following detailed description taken in conjunction with the accompanying drawings.

FIG. 1 is a block diagram illustrating an example of a storage device.

FIGS. 2A, 2B and 2C are circuit diagrams illustrating examples of a secondary power source.

FIG. 3 is a block diagram illustrating an example of a secondary power source, a charging circuit and a monitoring circuit.

FIGS. 4A, 4B and 4C are circuit diagrams illustrating examples of a first path and a second path that are included in a monitoring circuit.

FIGS. 5, 6A and 6B are diagrams illustrating an example of an operation of a storage device.

FIG. 7 is a block diagram illustrating an example of a control circuit.

FIGS. 8 and 9 are diagrams illustrating an example of a charging circuit.

FIG. 10 is a block diagram illustrating an example of a main system that is included in a storage device.

FIG. 11 is a block diagram illustrating an example of a storage controller.

FIG. 12 is a block diagram illustrating an example of a nonvolatile memory.

FIG. 13 is a flowchart illustrating an example of a method of monitoring a secondary power source.

FIG. 14 is a flowchart illustrating an example of a process of measuring a leakage current.

FIGS. 15 and 16 are flowcharts illustrating examples of proceses of determining whether a defect has occured in a secondary power source.

FIG. 17 is a flowchart illustrating an example of a method of monitoring a secondary power source.

FIG. 18 is a flowchart illustrating an example of a process of periodically performing a first monitoring operation and a second monitoring operation.

FIG. 19 is a diagram illustrating an operation of the process of FIG. 18.

FIG. 20 is a flowchart illustrating an example of a method of monitoring a secondary power source.

FIG. 21 is a flowchart illustrating an example of a process of checking an initial state of a secondary power source.

FIGS. 22A, 22B, 23A and 23B are diagrams illustrating examples of configurations and operations of a storage device.

FIG. 24 is a block diagram illustrating an example of a data center including a storage device.

### DETAILED DESCRIPTION

Like reference numerals refer to like elements throughout this application.

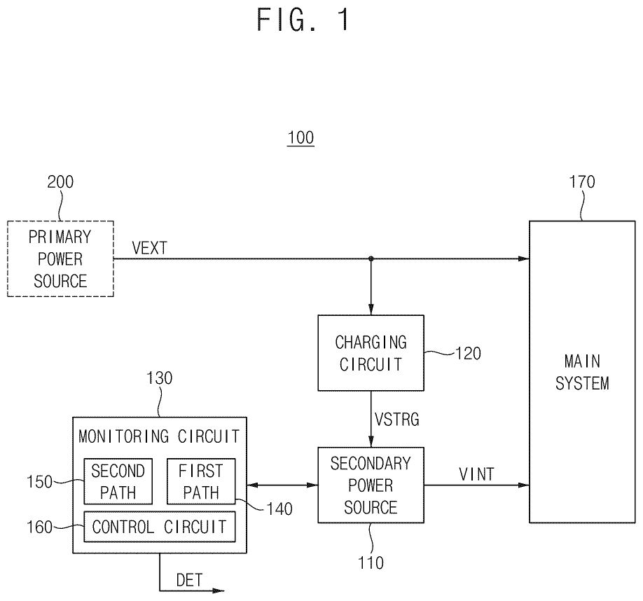

FIG. 1 is a block diagram illustrating a storage device according to some implementations of the present disclosure. Referring to FIG. 1, a storage device 100 includes a secondary power source 110, a charging circuit 120, a monitoring circuit 130 and a main system 170.

The main system 170 performs various tasks and/or functions for an operation of the storage device 100, and operates based on an external power supply voltage VEXT or an internal power supply voltage VINT.

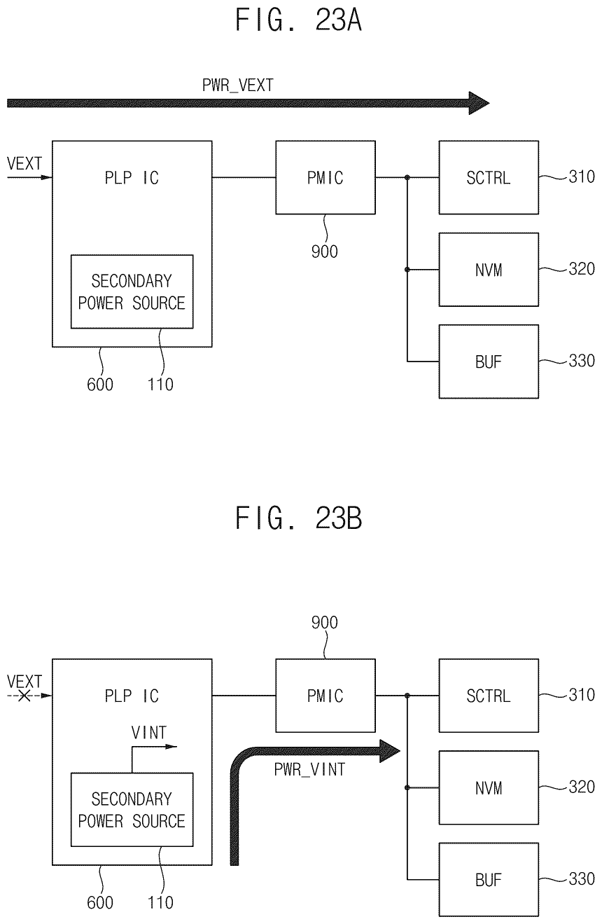

The external power supply voltage VEXT may be provided or supplied from a primary power source (or a main power device) 200 that is located or provided outside the storage device 100. The internal power supply voltage VINT may be provided or supplied from the secondary power source (or an auxiliary power device) 110 that is located or provided inside the storage device 100. A scheme of supplying power to the main system 170 may be changed depending on whether the external power supply voltage VEXT is normally supplied to the storage device 100, which will be described with reference to FIGS. 23A and 23B.

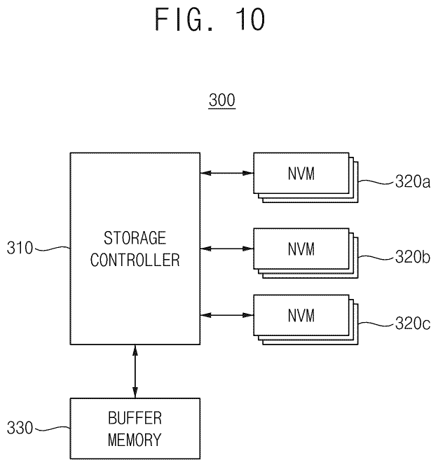

In some implementations, the main system 170 included in the storage device 100 includes a storage controller, a plurality of nonvolatile memories and a buffer memory. Detailed configurations of the components included in some implementations of the main system 170 will be described with reference to FIGS. 10 through 12. However, the main system is not limited to use as a storage medium, and may be applied, employed or extended to various electronic devices. For example, the main system can include components of a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automobile, etc.

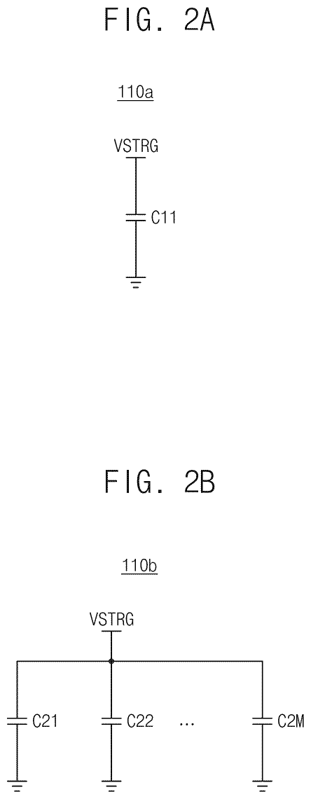

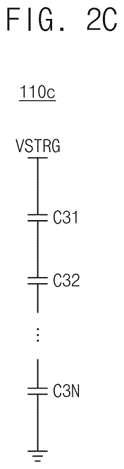

The secondary power source 110 includes at least one capacitor. The secondary power source 110 is charged based on a charging voltage VSTRG, and generates the internal power supply voltage VINT. Details on some implementations of the secondary power source 110 will be described with reference to FIGS. 2A, 2B and 2C.

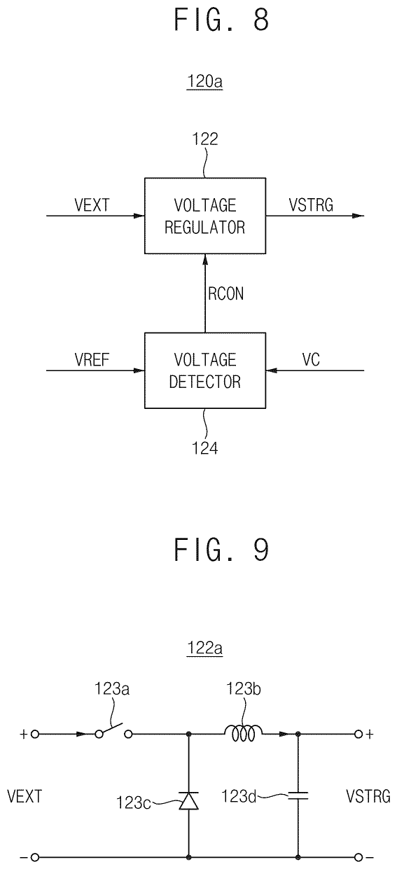

The charging circuit 120 generates the charging voltage VSTRG based on the external power supply voltage VEXT. In some implementations, the charging circuit 120 includes a DC-DC converter that converts the external power supply voltage VEXT, which is a direct current (DC) voltage, into the charging voltage VSTRG, which is a DC voltage. For example, the charging circuit 120 may have a configuration corresponding to a buck converter that converts a relatively high DC voltage into a relatively low DC voltage. As another example, the charging circuit 120 may have a configuration corresponding to a boost converter that converts a relatively low DC voltage into a relatively high DC voltage. In some implementations, the charging circuit 120 has a configuration corresponding to a buck-boost converter that converts an input DC voltage into a relatively high DC voltage and a relatively low DC voltage. Details on some implementations of the charging circuit 120 will be described with reference to FIGS. 8 and 9.

The monitoring circuit 130 is connected to the secondary power source 110. The monitoring circuit 130 detects whether the secondary power source 110 is defective (e.g., whether a defect or failure has occured in the secondary power source 110) by measuring a capacitance of the at least one capacitor included in the secondary power source 110 and a leakage current of the at least one capacitor included in the secondary power source 110. The monitoring circuit 130 includes a first path 140, a second path 150 and a control circuit 160.

The first path 140 is formed separately and/or independently from a leakage path of the at least one capacitor. The leakage current flows through the leakage path. The second path 150 is formed separately from the leakage path and the first path 140.

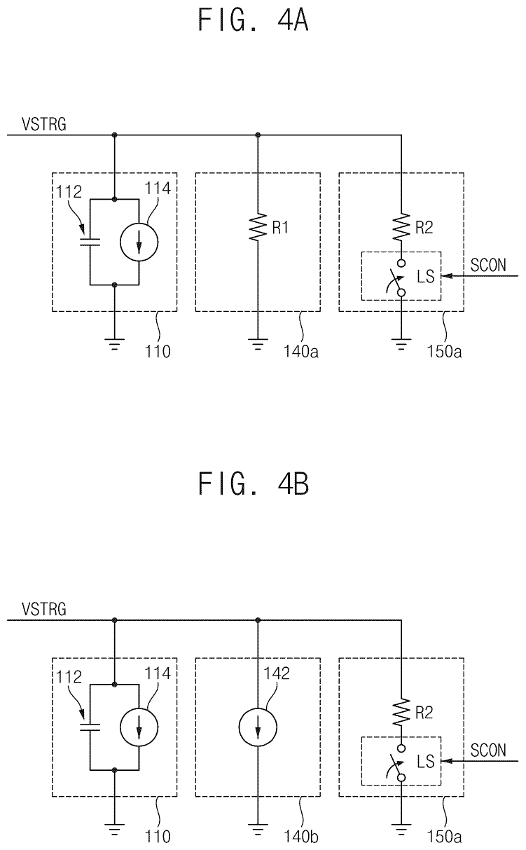

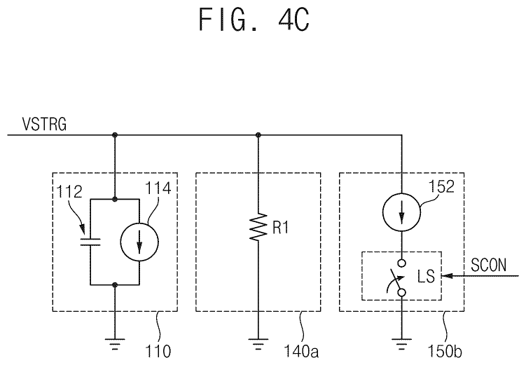

In some implementations, the first path 140 is a path that is always activated (or enabled) while or when the monitoring circuit 130 operates, and the second path 150 is a path that is selectively activated and deactivated (or disabled) while or when the monitoring circuit 130 operates. For example, each of the first path 140 and the second path 150 may include a resistor, a current source, etc. Detailed configurations of some implementations of the first path 140 and the second path 150 will be described with reference to FIGS. 4A, 4B and 4C.

The control circuit 160 controls activation and deactivation of the second path 150, calculates the leakage current while the second path is activated and deactivated, calculates the capacitance using the leakage current, determines whether the defect has occured in the secondary power source 110 based on at least one of the leakage current and the capacitance, and generates a determination signal DET representing or indicating a result of the determination.

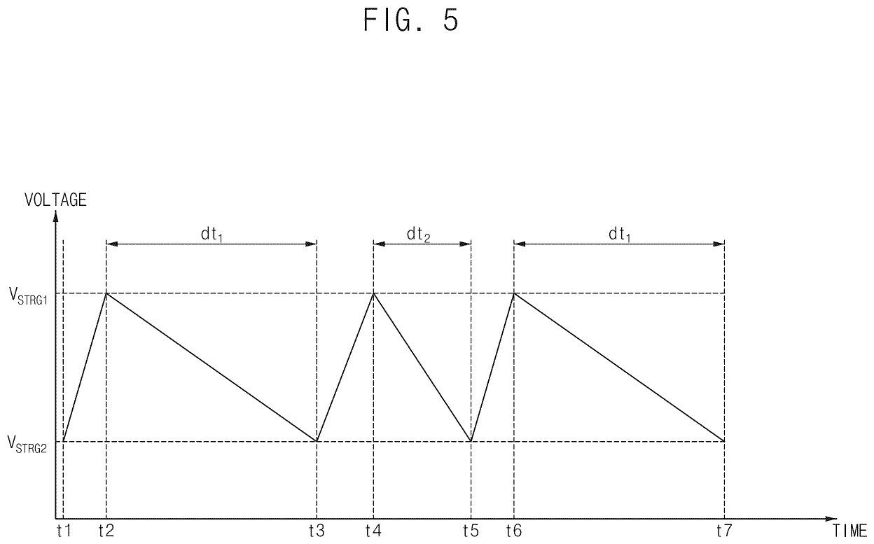

In some implementations, the control circuit 160 performs a first monitoring operation and a second monitoring operation. The first monitoring operation may represent an operation in which the capacitance is measured and/or calculated and it is determined based on the capacitance whether the defect has occured in the secondary power source 110. The second monitoring operation may represent an operation in which the leakage current is measured and/or calculated and it is determined based on the leakage current whether the defect has occured in the secondary power source 110. Such operations may be referred to as capacitor health monitoring (CHM) operations. For example, the first monitoring operation may be referred to as a real-time CHM operation, and the second monitoring operation may be referred to as a forced CHM operation. In some implementations, a cycle (or period) and/or the number of times in which the operation of measuring/calculating the capacitance and the first monitoring operation are performed is different from a cycle and/or the number of times in which the operation of measuring/calculating the leakage current and the second monitoring operation are performed. A detailed configuration and operation of some implementations of the control circuit 160 will be described with reference to FIGS. 5, 6A, 6B and 7.

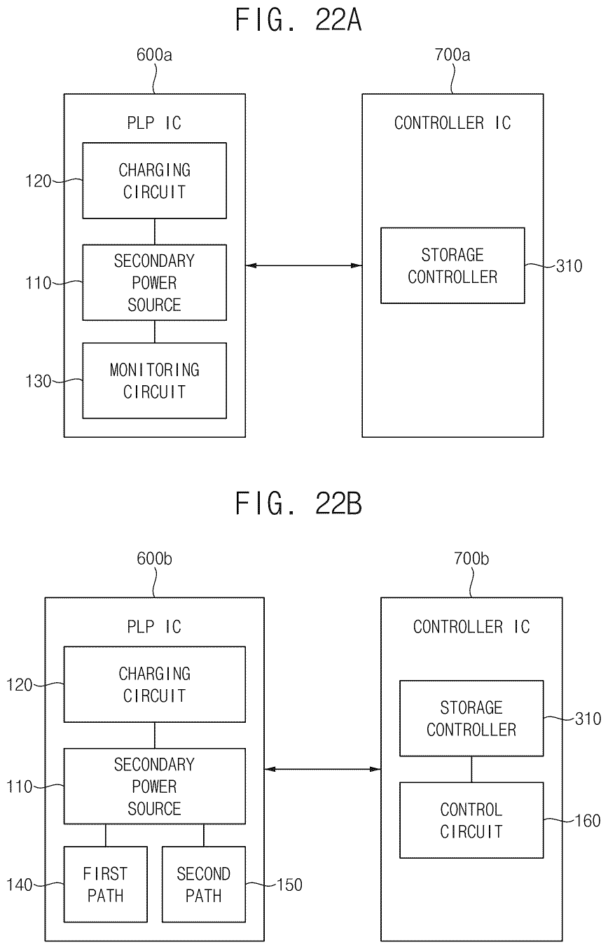

In some implementations, the secondary power source 110, the charging circuit 120 and the monitoring circuit 130 are included in the same chip (or integrated circuit (IC)). In some implementations, at least a part of the monitoring circuit 130 may be included in a chip separated and different from a chip including the secondary power source 110 and the charging circuit 120. A detailed arrangement of some implementations of the monitoring circuit 130 will be described with reference to FIGS. 22A and 22B.

The storage device 100 may include the first path 140 formed separately from the leakage path through which the leakage current flows in the secondary power source 110, and may further include the second path 150 formed separately from the leakage path and the first path 140. The leakage current may be calculated by performing two tests while the second path 150 is activated and deactivated, respectively, and it may be determined based on the leakage current whether a defect has occurred in the secondary power source 110. In addition, the capacitance of the at least one capacitor included in the secondary power source 110 may be calculated using the leakage current, and it may be determined based on the capacitance whether a defect has occurred in the secondary power source 110. Accordingly, defects in the secondary power source 110 may be efficiently detected, and operating performance and/or efficiency of the storage device 100 may be prevented from being degraded or deteriorated while keeping the storage device 100 safe.

FIGS. 2A, 2B and 2C are circuit diagrams illustrating examples of a secondary power source, e.g., the secondary power source 110 of FIG. 1.

Referring to FIG. 2A, a secondary power source 110a includes one capacitor C11. The capacitor C11 may be connected between the charging voltage VSTRG and a ground voltage (e.g., between a first node to which the charging voltage VSTRG is provided and a second node to which the ground voltage is provided), and may be charged based on the charging voltage VSTRG.

Referring to FIG. 2B, a secondary power source 110b includes a plurality of capacitors C21, C22, . . . , C2M, where M is a positive integer greater than or equal to two. The plurality of capacitors C21 to C2M may be connected in parallel to each other between the charging voltage VSTRG and the ground voltage, and may be charged based on the charging voltage VSTRG.

Referring to FIG. 2C, a secondary power source 110c includes a plurality of capacitors C31, C32, . . . , C3N, where N is a positive integer greater than or equal to two. The plurality of capacitors C31 to C3N may be connected in series between the charging voltage VSTRG and the ground voltage, and may be charged based on the charging voltage VSTRG.

In some implementations, each of the capacitors C11, C21 to C2M and C31 to C3N may be an electrolytic capacitor, a film capacitor, a tantalum capacitor, a ceramic capacitor, and/or the like. For example, the above-described capacitors may be distinguished based on a dielectric material included in each capacitor.

The electrolytic capacitor may use a thin oxide film for a dielectric and aluminum for an electrode, and thus may be referred to as an aluminum (Al) capacitor. The electrolytic capacitor may have good low-frequency properties and may be implemented with a high volume up to several tens of thousands of μF. The tantalum capacitor may include an electrode formed of tantalum (Ta) and may have greater temperature and frequency properties than those of the electrolytic capacitor.

The film capacitor may be structured such that a film dielectric such as polypropylene, polystyrol, Teflon, or the like, is inserted into an electrode such as aluminum, copper, or the like, and is rolled. The film capacitor may have a volume and a purpose that differs based on its material and manufacturing process. A biaxially-oriented polyethylene terephthalate (BoPET) capacitor, which may be relatively inexpensive among film capacitors, may be a cylindrical capacitor made by inserting a polyester film into metal, and may be used mainly for a high-frequency circuit, an oscillating circuit, or the like.

For the ceramic capacitor, a high-permittivity material such as titanium-barium may be used as a dielectric. The ceramic capacitor may have good high-frequency properties and may be used to pass noise through ground. A multi-layer ceramic condenser (MLCC), which is a type of ceramic capacitor, may use multi-layer high-permittivity ceramic as a dielectric between electrodes. The MLCC may be used for a bypass due to its good temperature and frequency properties and small size.

In some implementations, the capacitors C21 to C2M in FIG. 2B and/or the capacitors C31 to C3N in FIG. 2C may be homogeneous capacitors having the same characteristics. In some implementations, the capacitors C21 to C2M in FIG. 2B and/or the capacitors C31 to C3N in FIG. 2C may be heterogeneous capacitors having different characteristics.

However, the capacitor(s) are not limited thereto, and the secondary power source 110 may include capacitors having various configurations, characteristics, connection schemes, etc.

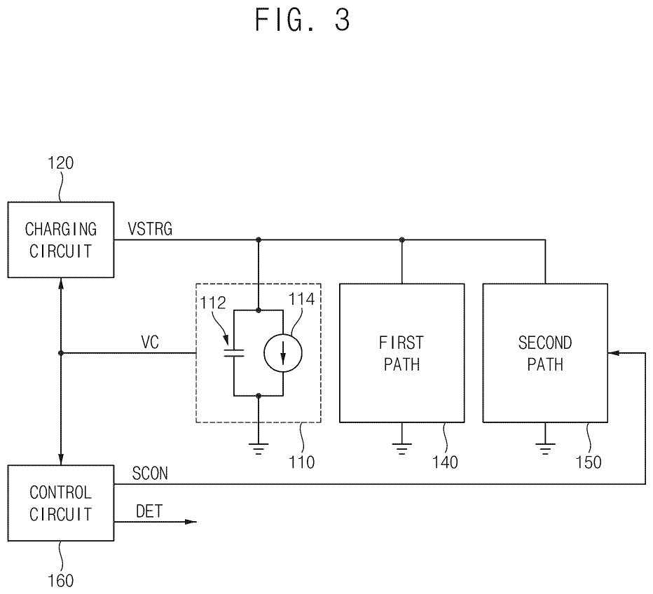

FIG. 3 is a block diagram illustrating an example of a secondary power source, a charging circuit and a monitoring circuit, e.g., the secondary power source 110, charging circuit 120, and monitoring circuit 130 included in the storage device of FIG. 1. The descriptions repeated with or overlapping with descriptions of FIG. 1 will be omitted in the interest of brevity.

Referring to FIGS. 1 and 3, the storage device 100 includes the secondary power source 110 and the charging circuit 120, and includes the first path 140, the second path 150 and the control circuit 160 that are included in the monitoring circuit 130. For convenience of illustration, the main system 170 is omitted in FIG. 3.

The secondary power source 110 includes a capacitor 112 and a current source 114. The capacitor 112 and the current source 114 may be connected in parallel to each other between the charging voltage VSTRG and the ground voltage (e.g., between the first node to which the charging voltage VSTRG is provided and the second node to which the ground voltage is provided or to which a ground connection is provided).

The capacitor 112 may be an equivalent capacitor of one or more capacitors that have various configurations and are included in the secondary power source 110 (e.g., the capacitor C11 in FIG. 2A, the capacitors C21 to C2M in FIG. 2B, the capacitors C31 to C3N in FIG. 2C, etc.).

The current source 114 may not be a physical component actually included in the secondary power source 110, and may be a component to represent a leakage path of the capacitor 112 through which the leakage current flows. For example, the capacitor 112 may, in some implementations, include an insulating resistor (e.g., a parasitic component) due to the capacitor's physical properties, and the leakage current of the capacitor 112 may flow through a path including the insulating resistor. For example, a current of current source 114 may correspond to the leakage current.

The first path 140 may be connected in parallel to the secondary power source 110 between the charging voltage VSTRG and the ground voltage. The second path 150 may be connected in parallel to the secondary power source 110 and the first path 140 between the charging voltage VSTRG and the ground voltage.

The charging circuit 120 may generate the charging voltage VSTRG, and may control the supply of the charging voltage VSTRG based on a capacitor voltage VC of the capacitor 112, e.g., a voltage over the capacitor 112 or a voltage that depends on the voltage over the capacitor 112. For example, as will be described with reference to FIG. 5, the capacitor voltage VC may repeatedly increase (or rise) and decrease (or fall) between a first voltage level V_{STRG1} and a second voltage level V_{STRG2} lower than the first voltage level V_{STRG1}. For example, when a voltage level of the capacitor voltage VC is higher than the first voltage level V_{STRG1}, the charging circuit 120 may stop supplying the charging voltage VSTRG. For example, when the voltage level of the capacitor voltage VC is lower than the second voltage level V_{STRG2}, the charging circuit 120 may supply the charging voltage VSTRG.

The control circuit 160 may generate a switch control signal SCON for controlling activation and deactivation of the second path 150, may measure and/or calculate the leakage current of the capacitor 112 and a capacitance of the capacitor 112 based on a change in voltage level of the capacitor voltage VC, may determine based on at least one of the leakage current and the capacitance whether the defect has occured in the secondary power source 110 (whether the secondary power source is defective), and may generate a determination signal DET representing a result of the determination. For example, when the leakage current is greater than or equal to a predetermined reference current, the control circuit 160 may determine that the defect has occured in the secondary power source 110. For example, when the capacitance is less than or equal to a predetermined reference capacitance, the control circuit 160 may determine that the defect has occured in the secondary power source 110.

FIGS. 4A, 4B and 4C are circuit diagrams illustrating examples of a first path and a second path, e.g., paths that may be included in the monitoring circuit of FIG. 3. The descriptions repeated with or overlapping with descriptions of FIG. 3 will be omitted in the interest of brevity.

Referring to FIG. 4A, a first path 140a may include a first resistor R1 that is connected between the charging voltage VSTRG and the ground voltage. A second path 150a may include a second resistor R2 and a leakage switch LS that are connected in series between the charging voltage VSTRG and the ground voltage. For example, the leakage switch LS may be turned on and off in response to the switch control signal SCON. For example, the leakage switch LS may include at least one transistor.

In some implementations, a first resistance of the first resistor R1 may be smaller than a resistance of the insulating resistor of the capacitor 112, and a second resistance of the second resistor R2 may be smaller than the resistance of the insulating resistor of the capacitor 112. For example, the amount of a first current flowing through the first path 140a and the first resistor R1 may be greater than the amount of the leakage current of the capacitor 112, and the second current flowing through the second path 150a and the second resistor R2 may be greater than the amount of the leakage current of the capacitor 112.

In some implementations, the second resistance may be smaller than the first resistance. For example, the amount of the second current may be greater than the amount of the first current.

In some implementations, at least one of the first resistor R1 and the second resistor R2 is a variable resistor.

Referring to FIG. 4B, a first path 140b may include a first current source 142 that is connected between the charging voltage VSTRG and the ground voltage. The first current source 142 may perform a function substantially the same as that of the first resistor R1 in FIG. 4A, e.g., to set a first current flowing through the first path. The second path 150a may be substantially the same as that described with reference to FIG. 4A.

Referring to FIG. 4C, the first path 140a may be substantially the same as that described with reference to FIG. 4A. A second path 150b may include a second current source 152 and a leakage switch LS that are connected in series between the charging voltage VSTRG and the ground voltage. The second current source 152 may perform a function substantially the same as that of the second resistor R2 in FIG. 4A, e.g., to set a second current flowing through the second path that is selectively switched on or off. The leakage switch LS may be substantially the same as that described with reference to FIG. 4A.

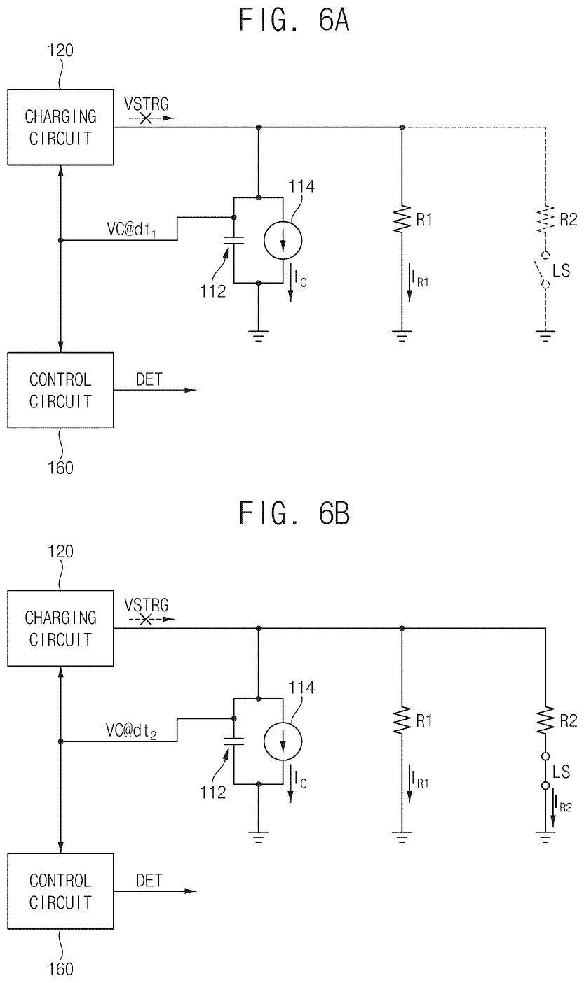

FIGS. 5, 6A and 6B are diagrams for describing an operation of a storage device (e.g., storage device 100) according to some implementations.

Referring to FIGS. 5, 6A and 6B, an operation of the storage device in which the first path 140a includes the first resistor R1 and the second path 150a includes the second resistor R2 and the leakage switch LS, which are described with reference to FIG. 4A, is illustrated.

As illustrated in FIG. 5, the capacitor voltage VC of the capacitor 112 may repeatedly increase and decrease between the first voltage level V_{STRG1} and the second voltage level V_{STRG2}.

For example, at time point t1, when the voltage level of the capacitor voltage VC becomes lower than the second voltage level V_{STRG2}, the charging circuit 120 may supply the charging voltage VSTRG. During a time interval between time points t1 and t2, the capacitor 112 may be charged based on the charging voltage VSTRG, and the voltage level of the capacitor voltage VC may increase. At time point t2, when the voltage level of the capacitor voltage VC becomes higher than the first voltage level V_{STRG1}, the charging circuit 120 may stop supplying the charging voltage VSTRG. During a time interval between time points t2 and t3, the capacitor 112 may be discharged, and the voltage level of the capacitor voltage VC may decrease. Similarly, the charging operation may be performed during a time interval between time points t3 and t4 and during a time interval between time points t5 and t6, and the discharge operation may be performed during a time interval between time points t4 and t5 and during a time interval between time points t6 and t7. Such charging and discharging operations may be repeatedly performed.

As illustrated in FIGS. 5 and 6A, during the time interval between time points t2 and t3, the leakage switch LS may be turned off (e.g., opened) based on the switch control signal SCON generated by the control circuit 160, and the second path 150a may be deactivated or disabled. In FIG. 6A, the deactivated second path 150a is illustrated by a dotted line. In this example, a leakage current I_{C} may flow through the capacitor 112, a first current I_{R1} may flow through the first resistor R1, and no current may flow through the second resistor R2.

While the second path 150a is deactivated, the control circuit 160 may measure a first time interval dt₁ during which the capacitor voltage VC@dt₁ decreases from the first voltage level V_{STRG1} to the second voltage level V_{STRG2}. The first time interval dt₁ may represent a time interval during which the voltage level of the capacitor voltage VC@dt₁ decreases due to the leakage current I_{C} and the first current I_{R1}, and may be referred to as a first discharging time interval.

Thereafter, as illustrated in FIGS. 5 and 6B, during the time interval between time points t4 and t5, the leakage switch LS may be turned on (e.g., closed) based on the switch control signal SCON generated by the control circuit 160, and the second path 150a may be activated or enabled. In this example, the leakage current I_{C} may flow through the capacitor 112, the first current I_{R1} may flow through the first resistor R1, and a second current I_{R2} may flow through the second resistor R2.

While the second path 150a is activated, the control circuit 160 may measure a second time interval dt₂ during which the capacitor voltage VC@dt₂ decreases from the first voltage level V_{STRG1} to the second voltage level V_{STRG2}. The second time interval dt₂ may represent a time interval during which the voltage level of the capacitor voltage VC@dt₂ decreases due to the leakage current I_{C}, the first current I_{R1} and the second current I_{R2}, and may be referred to as a second discharging time interval. For example, since the second current I_{R2} additionally flows in the example of FIG. 6B as compared with the example of FIG. 6A, the second time interval dt₂ may be shorter than the first time interval dt₁.

In addition, as illustrated in FIG. 5, the charging operation may be performed before and after the first time interval dt₁ and the second time interval dt₂ are measured, e.g., during the time interval between time points t1 and t2, during the time interval between time points t3 and t4, and during the time interval between time points t5 and t6,

In some implementations, the control circuit 160 calculates the leakage current I_{C} of the capacitor 112 based on the first time interval dt₁ and the second time interval dt₂. As described above, the measurement operation (or test operation) may be performed twice while the second path 150a is activated and deactivated, respectively, and the leakage current I_{C} may be calculated by assuming that the capacitance of the capacitor 112 is substantially the same in the two measurement operations. For example, the leakage current I_{C} may be obtained based on Equation 1, Equation 2, Equation 3, Equation 4, Equation 5, Equation 6, Equation 7 and Equation 8.

$$Q = CV \qquad [ Equation 1 ]$$

$$I = C \frac{dV}{dt} \qquad [ Equation 2 ]$$

$${dV}_{STRG} = {V}_{STRG 1} - {V}_{STRG 2} \qquad [ Equation 3 ]$$

$${I}_{R 1} ≅ \frac{{V}_{STRG 1} + {V}_{STRG 2}}{2 {R}_{1}} , {I}_{R 2} ≅ \frac{{V}_{STRG 1} + {V}_{STRG 2}}{2 {R}_{2}} \qquad [ Equation 4 ]$$

$${I}_{PLP} + {I}_{R 1} + {I}_{C} = {C}_{STRG} \frac{{dV}_{STRG}}{{dt}_{1}} \qquad [ Equation 5 ]$$

$${I}_{PLP} + {I}_{R 1} + {I}_{R 2} + {I}_{C} = {C}_{STRG} \frac{{dV}_{STRG}}{{dt}_{2}} \qquad [ Equation 6 ]$$

$$\frac{{I}_{R 2}}{{I}_{PLP} + {I}_{R 1} + {I}_{C}} = \frac{{dt}_{1}}{{dt}_{2}} - 1 \qquad [ Equation 7 ]$$

$${I}_{C} = \frac{{I}_{R 2}}{( \frac{{dt}_{1}}{{dt}_{2}} - 1 )} - {I}_{PLP} - {I}_{R 1} \qquad [ Equation 8 ]$$

In Equations 1 to 8, I_{C} denotes the leakage current, I_{R1} denotes the first current, I_{R2} denotes the second current, I_{PLP} denotes a current of a power-loss protection (PLP) integrated circuit (IC) including the secondary power source 110, dt₁ denotes the first time interval, dt₂ denotes the second time interval, V_{STRG1} denotes the first voltage level, and V_{STRG2} denotes the second voltage level. In addition, if I_{PLP} is omitted, Equation 5, Equation 6, Equation 7 and Equation 8 may be changed to Equation 9, Equation 10, Equation 11 and Equation 12, respectively.

$${I}_{R 1} + {I}_{C} = {C}_{STRG} \frac{{dV}_{STRG}}{{dt}_{1}} \qquad [ Equation 9 ]$$

$${I}_{R 1} + {I}_{R 2} + {I}_{C} = {C}_{STRG} \frac{{dV}_{STRG}}{{dt}_{2}} \qquad [ Equation 10 ]$$

$$\frac{{I}_{R 2}}{{I}_{R 1} + {I}_{C}} = \frac{{dt}_{1}}{{dt}_{2}} - 1 \qquad [ Equation 11 ]$$

$${I}_{C} = \frac{{I}_{R 2}}{( \frac{{dt}_{1}}{{dt}_{2}} - 1 )} - {I}_{R 1} \qquad [ Equation 12 ]$$

In some implementations, the control circuit 160 calculates a capacitance C_{STRG} of the capacitor 112 based on the leakage current I_{C}. For example, the capacitance C_{STRG} may be obtained based on Equation 13. In addition, if I_{PLP} is omitted, Equation 13 may be changed to Equation 14.

$${C}_{STRG} = ( {I}_{PLP} + {I}_{R 1} + {I}_{C} ) \frac{dt 1}{{V}_{STRG 1} - {V}_{STRG 2}} \qquad [ Equation 13 ]$$

$${C}_{STRG} = ( {I}_{R 1} + {I}_{C} ) \frac{dt 1}{{V}_{STRG 1} - {V}_{STRG 2}} \qquad [ Equation 14 ]$$

As described above, to calculate the leakage current I_{C}, both the first time interval dt₁ and the second time interval dt₂ may be measured. For example, both the operation between time points t2 and t3 in FIG. 5 (e.g., the operation in FIG. 6A) and the operation between time points t4 and t5 in FIG. 5 (e.g., the operation in FIG. 6B) may be performed to calculate the leakage current I_{C}. In this case, the activation and deactivation of the second path 150a should be controlled or forced, and thus the operations of calculating the leakage current I_{C} and determining based on the leakage current I_{C} whether the secondary power source is defective may be referred to as the forced CHM operation.

In some implementations, to calculate the capacitance C_{STRG}, only the first time interval dt₁ may be required. Accordingly, in some implementations, only the operation between time points t2 and t3 in FIG. 5 (e.g., the operation in FIG. 6A) may be performed to calculate the capacitance C_{STRG}. For example, only one measurement operation may be performed (e.g., while the second path 150a or 150b is deactivated), and thus the operations of calculating the capacitance C_{STRG} and determining based on the capacitance C_{STRG} whether the secondary power source is defective may be referred to as the real-time CHM operation. However, in some cases, to calculate the capacitance C_{STRG}, information associated with the leakage current I_{C} may be used (e.g., as in Equations 13-14), and thus, in some implementations, the operation of calculating the leakage current I_{C} is performed before the capacitance C_{STRG} is calculated

In some implementations, the first current I_{R1} and the second current I_{R2} are calculated based on the first resistance of the first resistor R1, the second resistance of the second resistor R2 and the charging voltage VSTRG. In some implementations, the first current I_{R1} and the second current I_{R2} are measured by a current measurer, e.g., a current measuring circuit.

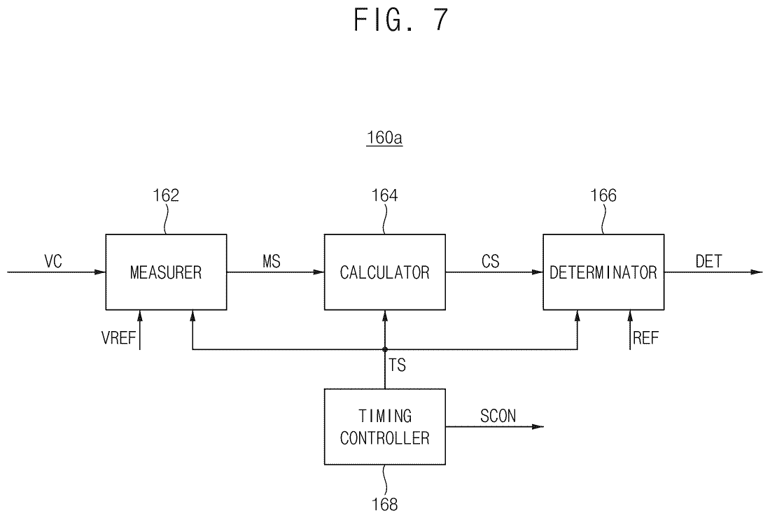

FIG. 7 is a block diagram illustrating an example of a control circuit, e.g., the control circuit 160 of FIG. 3.

Referring to FIG. 7, a control circuit 160a may include a measurer 162, a calculator 164, a determinator 166 and a timing controller 168. The measurer 162, the calculator 164, the determinator 166, and the timing controller 168 may be implemented as circuits, e.g., digital and/or analog circuits.

The measurer 162 may generate a measurement signal MS based on the capacitor voltage VC and reference voltage levels VREF. For example, the measurer 162 may measure the first time interval dt₁ during which the capacitor voltage VC decreases from the first voltage level V_{STRG1} to the second voltage level V_{STRG2} while the leakage switch LS is turned off, and may measure the second time interval dt₂ during which the capacitor voltage VC decreases from the first voltage level V_{STRG1} to the second voltage level V_{STRG2} while the leakage switch LS is turned on. For example, the reference voltage levels VREF may include the first voltage level V_{STRG1} to the second voltage level V_{STRG2}. For example, the measurement signal MS may include information associated with or related to (e.g., indicating) the first time interval dt₁ and the second time interval dt₂.

In some implementations, the measurer 162 may include a timer (e.g., a timer circuit), counter (e.g., a counter circuit), etc. for measuring time and/or time interval.

The calculator 164 may generate a calculation signal CS based on the measurement signal MS. For example, the calculator 164 may calculate the leakage current I_{C} based on the first time interval dt₁ and the second time interval dt₂, and may calculate the capacitance C_{STRG} based on the leakage current I_{C}. For example, the calculation signal CS may include information associated with (e.g., indicating) the leakage current I_{C} and/or the capacitance C_{STRG}.

The determinator 166 may generate the determination signal DET based on the calculation signal CS and reference values REF. For example, the determinator 166 may determine that the defect has occured in the secondary power source 110 (that the secondary power source 110 is defective) when the leakage current I_{C} is greater than or equal to the reference current, and may determine that the defect has occured in the secondary power source 110 (that the secondary power source 110 is defective) when the capacitance C_{STRG} is less than or equal to the reference capacitance. For example, the reference values REF may include the reference current and the reference capacitance. For example, the determination signal DET may have a first logic level (e.g., a logic high level) when it is determined that the defect has occured in the secondary power source 110, and may have a second logic level (e.g., a logic low level) when it is determined that no defect has occured in the secondary power source 110. For example, when the defect has occured in the secondary power source 110, the first time interval dt₁ and the second time interval dt₂ may decrease as compared with a case where no defect has occured in the secondary power source 110.

In some implementations, a part or all of the calculator 164 and the determinator 166 may be implemented in the form of hardware or in the form of software executed by a processor. For example, the determinator 166 may include a component for storing the leakage current I_{C} that is the most recently calculated.

The timing controller 168 may generate a timing control signal TS for controlling operation timings of the measurer 162, the calculator 164 and the determinator 166, and may generate the switch control signal SCON for turning on and off the leakage switch LS.

FIGS. 8 and 9 are diagrams illustrating an example of a charging circuit, e.g., the charging circuit 120 of FIG. 1.

Referring to FIG. 8, a charging circuit 120a may include a voltage regulator 122 and a voltage detector 124.

The voltage regulator 122 may generate the charging voltage VSTRG based on the external power supply voltage VEXT, and may supply the charging voltage VSTRG or stop supplying the charging voltage VSTRG based on a control signal RCON.

The voltage detector 124 may generate the control signal RCON based on the capacitor voltage VC and the reference voltage levels VREF. For example, the voltage detector 124 may generate the control signal RCON for controlling an operation of the voltage regulator 122 such that the supply of the charging voltage VSTRG is stopped when the voltage level of the capacitor voltage VC is higher than the first voltage level V_{STRG1} and the charging voltage VSTRG is supplied when the voltage level of the capacitor voltage VC is lower than the second voltage level V_{STRG2}. For example, the reference voltage levels VREF may include the first voltage level V_{STRG1} and the second voltage level V_{STRG2}.

Referring to FIG. 9, a voltage regulator 122a may include a switch 123a, an inductor 123b, a diode 123c and a capacitor 123d. For example, the voltage regulator 122a may be a buck converter that steps down the external power supply voltage VEXT, which is an input DC voltage, and provides the charging voltage VSTRG, which is an output DC voltage.

When the switch 123a is closed, the external power supply voltage VEXT, which is the input DC voltage, may be provided to the inductor 123b, so a current flowing through the inductor 123b may increase. As such, energy may be accumulated in the inductor 123b and may be delivered to an output terminal, and thus the charging voltage VSTRG, which is the output DC voltage and corresponds to a voltage of the capacitor 123d, may increase. The diode 123c may be reverse-biased, such that a current may not flow to the diode 123c.

When the switch 123a is opened, a closed circuit including the inductor 123b, the diode 123c and the capacitor 123d may be formed. The current flowing through the inductor 123b may flow through the closed circuit and may be slowly dropped, and thus the output DC voltage, e.g., the voltage of the capacitor 123d, may decrease. An average voltage of the output DC voltage may be controlled depending on a ratio of closed to opened time of the switch 123a. When the switch 123a is closed, a maximum output DC voltage may be reached, and the output DC voltage may be equal to or less than the input DC voltage.

However, the charging circuit is not limited thereto, and various implementations of the charging circuit may be included.

FIG. 10 is a block diagram illustrating an example of a main system, e.g., the main system 170 of FIG. 1.

Referring to FIG. 10, a main system 300 may include a storage controller 310, a plurality of nonvolatile memories (NVMs) 320a, 320b and 320c, and a buffer memory 330.

The storage controller 310 may control an operation of a storage device (e.g., the storage device 100 of FIG. 1) including the main system 300. For example, the storage controller 310 may control operations of the plurality of nonvolatile memories 320a to 320c based on commands and data that are received from a host device located outside the storage device.

The plurality of nonvolatile memories 320a to 320c may be controlled by the storage controller 310, and may store a plurality of data. For example, the plurality of nonvolatile memories 320a to 320c may store meta data, various user data, or the like. The plurality of nonvolatile memories 320a to 320c may store various types of data.

In some implementations, each of the plurality of nonvolatile memories 320a to 320c includes a NAND flash memory. In some implementations, each of the plurality of nonvolatile memories 320a to 320c includes one of a phase-change random access memory (PRAM), a resistive random access memory (RRAM), a magnetic random access memory (MRAM), a ferroelectric random access memory (FRAM), or the like.

The buffer memory 330 may be controlled by the storage controller 310, may store instructions and/or data that are executed and/or processed by the storage controller 310, and may temporarily store data stored in or to be stored into the plurality of nonvolatile memories 320a to 320c. For example, the buffer memory 330 may include at least one of various volatile memories, e.g., a dynamic random access memory (DRAM), or the like.

In some implementations, the storage device may be a solid state drive (SSD). In some implementations, the storage device may be a universal flash storage (UFS), a multimedia card (MMC) or an embedded multimedia card (eMMC). In some implementations, the storage device may be one of a secure digital (SD) card, a micro SD card, a memory stick, a chip card, a universal serial bus (USB) card, a smart card, a compact flash (CF) card, or the like.

In some implementations, the storage device may be connected to the host device via a block accessible interface which may include, for example, a UFS, an eMMC, a serial advanced technology attachment (SATA) bus, a nonvolatile memory express (NVMe) bus, a small computer system interface (SCSI) bus, a serial attached SCSI (SAS) bus, or the like. The storage device may use a block accessible address space corresponding to an access size of the plurality of nonvolatile memories 320a to 320c to provide the block accessible interface to the host device, for allowing the access by units of a memory block with respect to data stored in the plurality of nonvolatile memories 320a to 320c c.

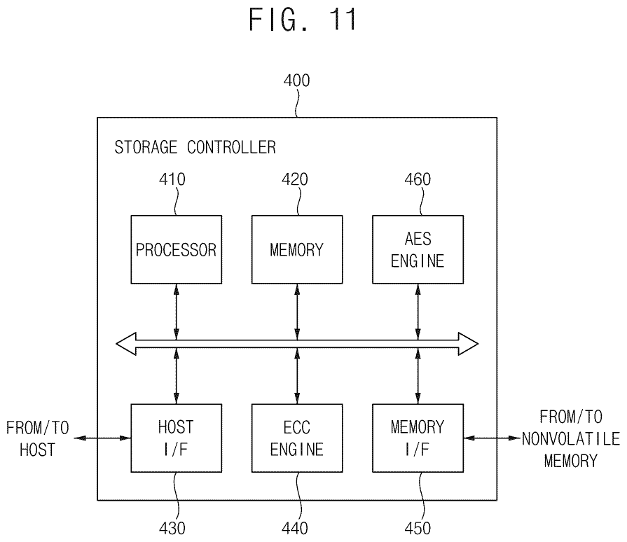

FIG. 11 is a block diagram illustrating an example of a storage controller, e.g., the storage controller 310 of FIG. 10.

Referring to FIG. 11, a storage controller 400 may include at least one processor 410, a memory 420, a host interface (I/F) 430, an error correction code (ECC) engine 440, a memory interface 450 and an advanced encryption standard (AES) engine 460.

The processor 410 may control an operation of the storage controller 400 in response to commands received via the host interface 430 from a host device located outside a storage device (e.g., the storage device 100 of FIG. 1). In some implementations, the processor 410 controls respective components by employing firmware for operating the storage device including the storage controller 400.

The memory 420 may store instructions and data that are executed and processed by the processor 410. For example, the memory 420 may include a volatile memory, such as a DRAM, a static random access memory (SRAM), a cache memory, or the like.

The ECC engine 440 for error correction may perform coded modulation using a Bose-Chaudhuri-Hocquenghem (BCH) code, a low density parity check (LDPC) code, a turbo code, a Reed-Solomon code, a convolution code, a recursive systematic code (RSC), a trellis-coded modulation (TCM), a block coded modulation (BCM), etc., or may perform ECC encoding and ECC decoding using above-described codes or other error correction codes.

The host interface 430 may provide physical connections between the host device and the storage device. The host interface 430 may provide an interface corresponding to a bus format of the host for communication between the host device and the storage device.

The memory interface 450 may exchange data with nonvolatile memories (e.g., the nonvolatile memories 320a to 320c in FIG. 10) included in the storage device. The memory interface 450 may transfer data to the nonvolatile memories, or may receive data read from the nonvolatile memories. In some implementations, the memory interface 450 is connected to the nonvolatile memories via one channel. In some implementations, the memory interface 450 is connected to the nonvolatile memories via two or more channels. For example, the memory interface 450 may be configured to comply with a standard protocol, such as Toggle or open NAND flash interface (ONFI).

The AES engine 460 may perform at least one of an encryption operation and a decryption operation on data input to the storage controller 400 by using a symmetric-key algorithm. In some implementations, the AES engine 460 includes an encryption module and a decryption module. For example, the encryption module and the decryption module may be implemented as separate modules. As another example, one module capable of performing both encryption and decryption operations may be implemented in the AES engine 460.

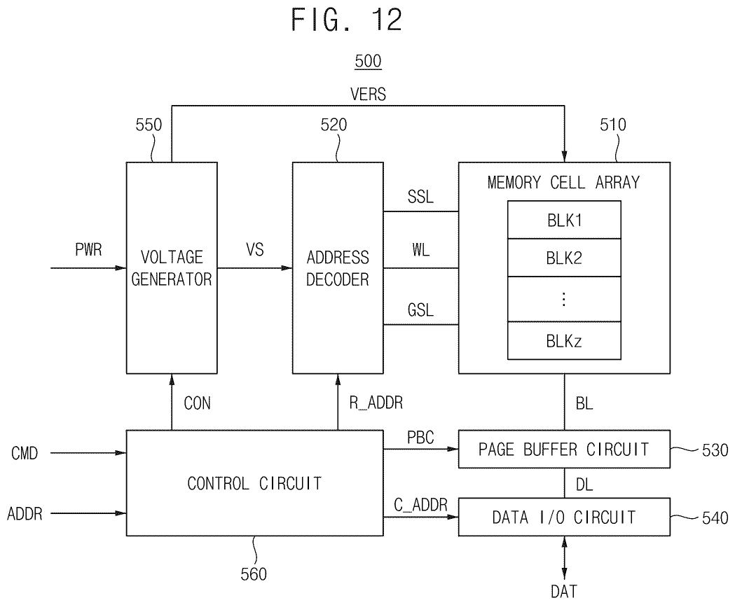

FIG. 12 is a block diagram illustrating an example of a nonvolatile memory, e.g., an NVM 320a-320c of FIG. 10.

Referring to FIG. 12, a nonvolatile memory 500 may include a memory cell array 510, an address decoder 520, a page buffer circuit 530, a data input/output (I/O) circuit 540, a voltage generator 550 and a control circuit 560.

The memory cell array 510 may be connected to the address decoder 520 via a plurality of string selection lines SSL, a plurality of wordlines WL and a plurality of ground selection lines GSL. The memory cell array 510 may be further connected to the page buffer circuit 530 via a plurality of bitlines BL. The memory cell array 510 may include a plurality of memory cells (e.g., a plurality of nonvolatile memory cells) that are connected to the plurality of wordlines WL and the plurality of bitlines BL. The memory cell array 510 may be divided into a plurality of memory blocks BLK1, BLK2, . . . , BLKz each of which includes memory cells. In addition, each of the plurality of memory blocks BLK1 to BLKz may be divided into a plurality of pages.

In some implementations, the plurality of memory cells are arranged in a two-dimensional (2D) array structure or a three-dimensional (3D) vertical array structure. A 3D vertical array structure may include vertical cell strings that are vertically oriented such that at least one memory cell is located over another memory cell. The at least one memory cell may include a charge trap layer. The following patent documents, which are hereby incorporated by reference in their entirety, describe suitable configurations for a memory cell array including a 3D vertical array structure, in which the three-dimensional memory array is configured as a plurality of levels, with wordlines and/or bitlines shared between levels: U.S. Pat. Nos. 7,679,133; 8,553,466; 8,654,587; 8,559,235; and US Pat. Pub. No. 2011/0233648.

The control circuit 560 may receive a command CMD and an address ADDR from the outside (e.g., the host device and/or the storage controller), and may control erasure, programming and read operations of the nonvolatile memory 500 based on the command CMD and the address ADDR. An erasure operation may include performing a sequence of erase loops, and a programming operation may include performing a sequence of program loops. Each erase loop may include an erase operation and an erase verification operation. Each program loop may include a program operation and a program verification operation. The read operation may include a normal read operation and a data recovery read operation.

For example, the control circuit 560 may generate control signals CON, which are used for controlling the voltage generator 550, and may generate control signal PBC for controlling the page buffer circuit 530, based on the command CMD, and may generate a row address R_ADDR and a column address C_ADDR based on the address ADDR. The control circuit 560 may provide the row address R_ADDR to the address decoder 520 and may provide the column address C_ADDR to the data I/O circuit 540.

The address decoder 520 may be connected to the memory cell array 510 via the plurality of string selection lines SSL, the plurality of wordlines WL and the plurality of ground selection lines GSL. For example, in the data erase/write/read operations, the address decoder 520 may determine at least one of the plurality of wordlines WL as a selected wordline, may determine at least one of the plurality of string selection lines SSL as a selected string selection line, and may determine at least one of the plurality of ground selection lines GSL as a selected ground selection line, based on the row address R_ADDR.

The voltage generator 550 may generate voltages VS that are required for an operation of the nonvolatile memory 500 based on a power PWR and the control signals CON. The voltages VS may be applied to the plurality of string selection lines SSL, the plurality of wordlines WL and the plurality of ground selection lines GSL via the address decoder 520. In addition, the voltage generator 550 may generate an erase voltage VERS that is required for the data erase operation based on the power PWR and the control signals CON. The erase voltage VERS may be applied to the memory cell array 510 directly or via the bitline BL. For example, the power PWR may correspond to the external power supply voltage VEXT or the internal power supply voltage VINT in FIG. 1.

The page buffer circuit 530 may be connected to the memory cell array 510 via the plurality of bitlines BL. The page buffer circuit 530 may include a plurality of page buffers. The page buffer circuit 530 may store data DAT to be programmed into the memory cell array 510 or may read data DAT sensed from the memory cell array 510. For example, the page buffer circuit 530 may operate as a write driver or a sensing amplifier depending on an operation mode of the nonvolatile memory 500.

The data I/O circuit 540 may be connected to the page buffer circuit 530 via data lines DL. The data I/O circuit 540 may provide the data DAT from an outside of the nonvolatile memory 500 to the memory cell array 510 via the page buffer circuit 530 or may provide the data DAT from the memory cell array 510 to the outside of the nonvolatile memory 500, based on the column address C_ADDR.

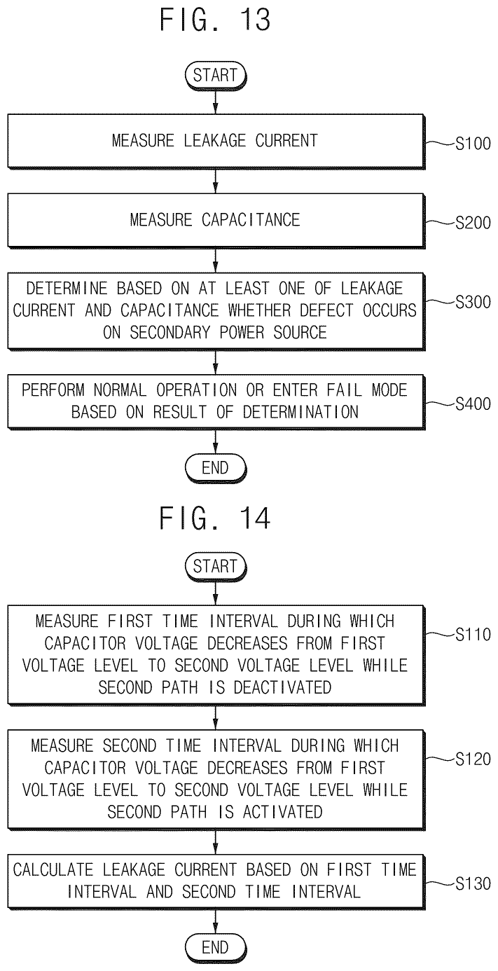

FIG. 13 is a flowchart illustrating a method of monitoring a secondary power source according to some implementations of the present disclosure.

Referring to FIG. 13, a method of monitoring a secondary power source is performed by a storage device (or an electronic device) that includes a secondary power source, a charging circuit and a monitoring circuit. For example, the storage device and components thereof may be implemented as described with reference to FIGS. 1 through 12.

In the method of FIG. 13, a leakage current of at least one capacitor included in the secondary power source is measured (operation S100). For example, operation S100 may be performed by the monitoring circuit 130 in FIG. 1, and the leakage current may be calculated based on monitoring while the second path 150 included in the monitoring circuit 130 is activated and deactivated. Operation S100 will be described with reference to FIG. 14.

A capacitance of the at least one capacitor is measured using the leakage current (operation S200). For example, operation S200 may be performed by the monitoring circuit 130 in FIG. 1, and the capacitance may be calculated using the leakage current while the second path 150 is deactivated.

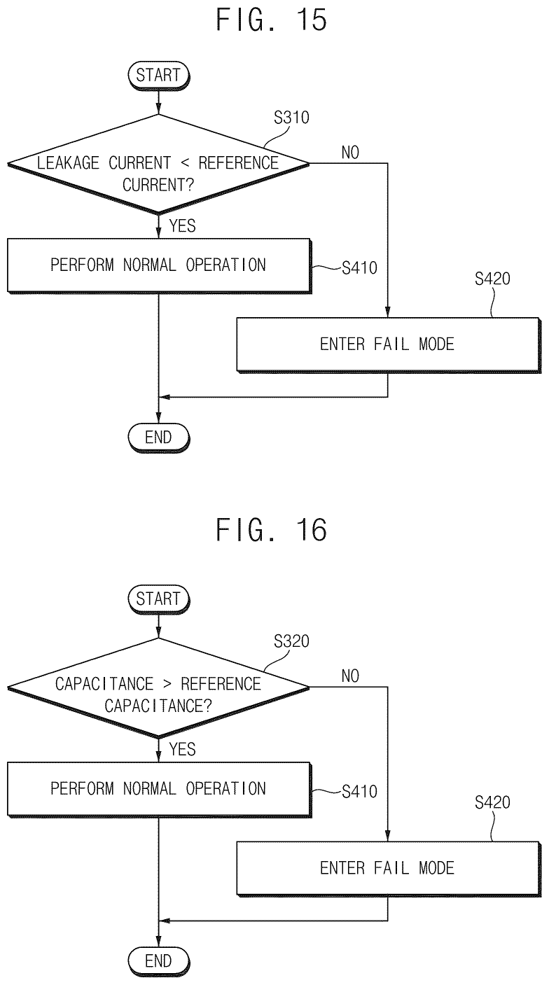

It is determined based on at least one of the leakage current and the capacitance whether a defect has occured in the secondary power source (whether the secondary power source is defective) (operation S300). Based on a result of the determination, the storage device may perform a normal operation or may enter a fail mode (operation S400). For example, operations S300 and S400 may be performed by monitoring circuit 130 in FIG. 1. Operations S300 and S400 will be described with reference to FIGS. 15 and 16.

FIG. 14 is a flowchart illustrating an example of measuring a leakage current in FIG. 13.

Referring to FIGS. 13 and 14, in operation S100, the first time interval dt₁ during which the capacitor voltage VC decreases from the first voltage level V_{STRG1} to the second voltage level V_{STRG2} may be measured while the second path 150 is deactivated (operation S110). The second time interval dt₂ during which the capacitor voltage VC decreases from the first voltage level V_{STRG1} to the second voltage level V_{STRG2} may be measured while the second path 150 is activated (operation S120). For example, operations S110 and S120 may be performed by the measurer 162 in FIG. 7.

The leakage current may be calculated based on the first time interval dt₁ and the second time interval dt₂ (operation S130). For example, operation S130 may be performed by the calculator 164 in FIG. 7, and may be performed based on Equation 8 or Equation 12. For example, the calculated leakage current may be stored.

In operation S200, the first time interval dt₁ during which the capacitor voltage VC decreases from the first voltage level V_{STRG1} to the second voltage level V_{STRG2} may be measured while the second path 150 is deactivated similarly to operation S110, and the capacitance may be calculated based on the measured first time interval dt₁ and the leakage current calculated in S130. For example, the above-described operations in S200 may be performed by the measurer 162 and the calculator 164 in FIG. 7, and may be performed based on Equation 13 or Equation 14.

FIGS. 15 and 16 are flowcharts illustrating examples of determining whether a defect has occured in the secondary power source and performing a normal operation or entering a fail mode, e.g., corresponding to operation S400.

Referring to FIGS. 13 and 15, an example of the determination operation based on the leakage current is illustrated.

For example, in operation S300, the leakage current may be compared with the reference current (operation S310). For example, operation S310 may be performed by the determinator 166 in FIG. 7.

When the leakage current is less than the reference current (operation S310: YES), it may be determined that no defect has occured in the secondary power source, and the storage device may perform the normal operation in S400 (operation S410). For example, the normal operation may include various operations of the storage device based on requests from a host device, e.g., a data write operation, a data read operation, a data erase operation, etc. For example, the normal operation may include management operations performed by the storage device itself, e.g., a garbage collection operation, etc.

When the leakage current is greater than or equal to the reference current (operation S310: NO), it may be determined that a defect has occured in the secondary power source, and the storage device may enter the fail mode in S400 (operation S420). For example, in the fail mode, an operation of the storage device may be stopped (e.g., the storage service may be terminated), or a usage of a buffer memory included in the storage device may be stopped (e.g., the DRAM-less service may be provided without using the buffer memory).

A power-loss protection (PLP) operation or PLP dump operation in the storage device may represent that the storage device is operating based on the internal power supply voltage (or auxiliary power supply voltage) VINT for a certain time interval even when the external power supply voltage VEXT is blocked (e.g., in a sudden power-off (SPO) situation in which the supply of the external power supply voltage VEXT is suddenly interrupted). For example, while the PLP operation is performed, a reset operation or a flush operation may be performed on the storage device based on the internal power supply voltage VINT such that the operation of the storage device is normally terminated before the internal power supply voltage VINT is turned off. For example, during the PLP operation, data in the buffer memory 330 may be moved to the nonvolatile memory 320. However, after the defect has occured in the secondary power source, the PLP operation may not be performed, and thus the storage device may enter the fail mode as described above.

Referring to FIGS. 13 and 16, an example of the determination operation based on the capacitance is illustrated.

For example, in operation S300, the capacitance may be compared with the reference capacitance (operation S320). For example, operation S320 may be performed by the determinator 166 in FIG. 7.

When the capacitance is greater than the reference capacitance (operation S320: YES), it may be determined that no defect has occured in the secondary power source, and the storage device may perform the normal operation in S400 (operation S410). When the capacitance is less than or equal to the reference capacitance (operation S320: NO), it may be determined that the defect has occured in the secondary power source, and the storage device may enter the fail mode in S400 (operation S420). Operations S410 and S420 may be substantially the same as those described with reference to FIG. 15.

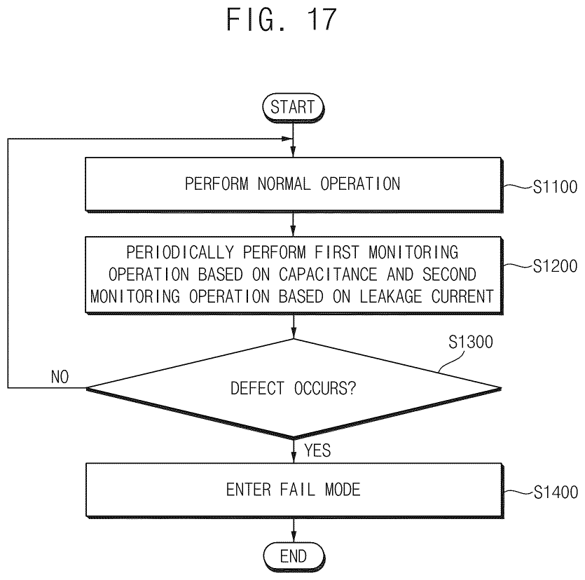

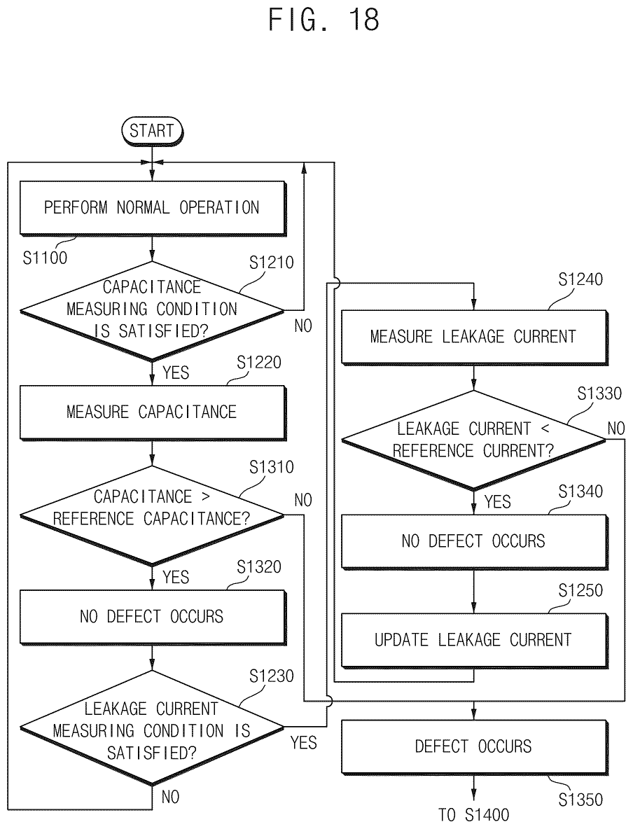

FIG. 17 is a flowchart illustrating a method of monitoring a secondary power source according to some implementations. The descriptions repeated with or overlapping with descriptions of FIGS. 13, 14, 15 and 16 will be omitted in the interest of brevity.

Referring to FIG. 17, the storage device is powered on and operates, and performs a normal operation (operation S1100). For example, operation S1100 may be substantially the same as operation S410 in FIGS. 15 and 16.

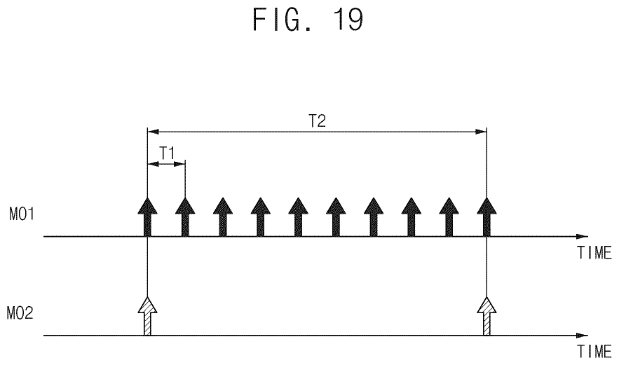

While the storage device is operating, a first monitoring operation and a second monitoring operation are performed periodically and/or repeatedly (operation S1200). The first monitoring operation represents an operation in which it is determined based on a capacitance of at least one capacitor included in the secondary power source whether the defect has occured in the secondary power source. The second monitoring operation represents an operation in which it is determined based on a leakage current of the at least one capacitor whether the defect has occured in the secondary power source. For example, the first monitoring operation may be similar to operation S200 in FIG. 13 and operation S320 in FIG. 16, and the second monitoring operation may be similar to operation S100 in FIG. 13 and operation S310 in FIG. 15. For example, a cycle of the first monitoring operation and/or the number of times the first monitoring operation is performed may be different from a cycle of the second monitoring operation and/or the number of times the second monitoring operation is performed. Operation S1200 will be described with reference to FIGS. 18 and 19.

When it is determined based on at least one of the first and second monitoring operations that no defect has occured in the secondary power source (operation S1300: NO), the normal operation in S1100 may continue to be performed. When it is determined based on at least one of the first and second monitoring operations that a defect has occured in the secondary power source (operation S1300: YES), the storage device may enter a fail mode (operation S1400). For example, operation S1400 may be substantially the same as operation S420 in FIGS. 15 and 16.

FIGS. 17-18 are flowcharts illustrating an example of periodically performing a first monitoring operation and a second monitoring operation. FIG. 19 is a diagram for describing operations of FIGS. 17-18.

Referring to FIGS. 17, 18 and 19, while the normal operation is performed (operation S1100), it may be checked or detected whether a first condition for performing a first operation and a first monitoring operation MO1 is satisfied (operation S1210). The first operation may represent an operation of measuring the capacitance, and the first monitoring operation MO1 may represent an operation of determining based on the capacitance whether the defect has occured in the secondary power source. For example, as illustrated in FIG. 19, the first operation and the first monitoring operation MO1 may be performed every first cycle T1, and it may be checked whether the first cycle T1 has elapsed since the first operation and the first monitoring operation MO1 were previously performed. For example, the first condition may be a timing condition of whether the first cycle T1 has elapsed.

When the first condition is satisfied (operation S1210: YES), the first operation of measuring the capacitance may be performed (operation S1220), and the first monitoring operation MO1 of determining based on the capacitance whether the defect has occured in the secondary power source may be performed by comparing the capacitance with the reference capacitance (operation S1310). For example, operations S1220 and S1310 may be substantially the same as operation S200 in FIG. 13 and operation S320 in FIG. 16, respectively. When the first condition is not satisfied (operation S1210: NO), the normal operation in S1100 may continue to be performed.

When the capacitance is greater than the reference capacitance (operation S1310: YES), it may be determined that no defect has occured in the secondary power source (operation S1320).

Thereafter, it may be checked or detected whether a second condition for performing a second operation and a second monitoring operation MO2 is satisfied (operation S1230). The second operation may represent an operation of measuring the leakage current, and the second monitoring operation MO2 may represent an operation of determining based on the leakage current whether the defect has occured in the secondary power source. For example, as illustrated in FIG. 19, the second operation and the second monitoring operation MO2 may be performed every second cycle T2, which is longer than the first cycle T1, and it may be checked whether the second cycle T2 has elapsed since the second operation and the second monitoring operation MO2 were previously performed. As another example, the second operation and the second monitoring operation MO2 may be performed when a first number of times the first operation and the first monitoring operation MO1 are performed is greater than or equal to a predetermined reference number of times, and it may be checked whether the first number of times is greater than or equal to the reference number by counting the first number of times. In the example of FIG. 19, the reference number of times is nine.

When the second condition is satisfied (operation S1230: YES), the second operation of measuring the leakage current may be performed (operation S1240), and the second monitoring operation MO2 of determining based on the leakage current whether the defect has occured in the secondary power source may be performed by comparing the leakage current with the reference current (operation S1330). For example, operations S1240 and S1330 may be substantially the same as operation S100 in FIG. 13 and operation S310 in FIG. 15, respectively. When the second condition is not satisfied (operation S1230: NO), the normal operation in S1100 may continue to be performed.

When the leakage current is less than the reference current (operation S1330: YES), it may be determined that no defect has occured in the secondary power source (operation S1340). In this case, in some implementations, the leakage current may be updated (operation S1250), e.g., the latest leakage current measured in S1240 may be stored (e.g., for subsequent calculation of the capacitance), and the normal operation in S1100 may continue to be performed.

When the capacitance is less than or equal to the reference capacitance (operation S1310: NO), or when the leakage current is greater than or equal to the reference current (operation S1330: NO), it may be determined that the defect has occured in the secondary power source (operation S1350), and the storage device may enter the fail mode in S1400.

In some implementations, as the above-described operations are performed, the first cycle T1 in which the first operation and the first monitoring operation MO1 are performed may be shorter than the second cycle T2 in which the second operation and the second monitoring operation MO2 are performed.

In some implementations, as the above-described operations are performed, during a predetermined time interval, the first number of times the first operation and the first monitoring operation MO1 are performed may be greater than the second number of times the second operation and the second monitoring operation MO2 are performed. For example, the first monitoring operation MO1 may be repeatedly performed, and the second monitoring operation MO2 may be performed when the first number of times is greater than or equal to a reference number of times, e.g., a reference number that is at least two.

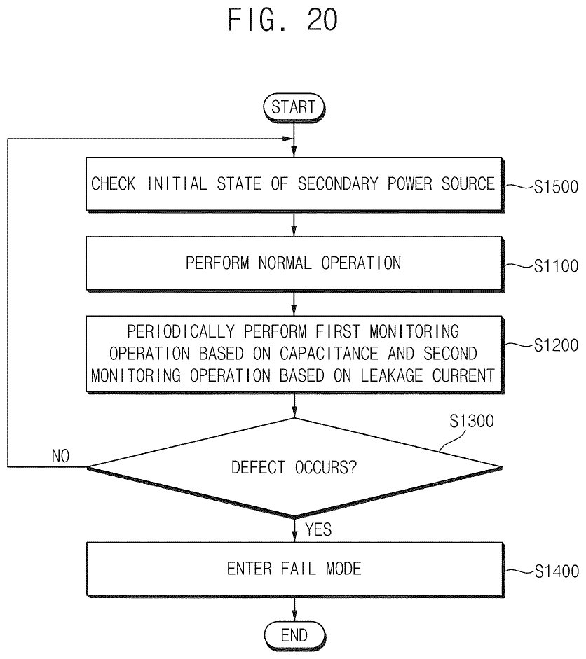

FIG. 20 is a flowchart illustrating a method of monitoring a secondary power source according to some implementations. The descriptions repeated with or overlapping with descriptions of FIG. 17 will be omitted in the interest of brevity.

Referring to FIG. 20, in a method of monitoring a secondary power source according to some implementations, an initial state of the secondary power source may be checked at an initial operating time (or at the beginning of operation) (operation S1500). Thereafter, operations S1100, S1200, S1300 and S1400 may be substantially the same as those described with reference to FIG. 17.

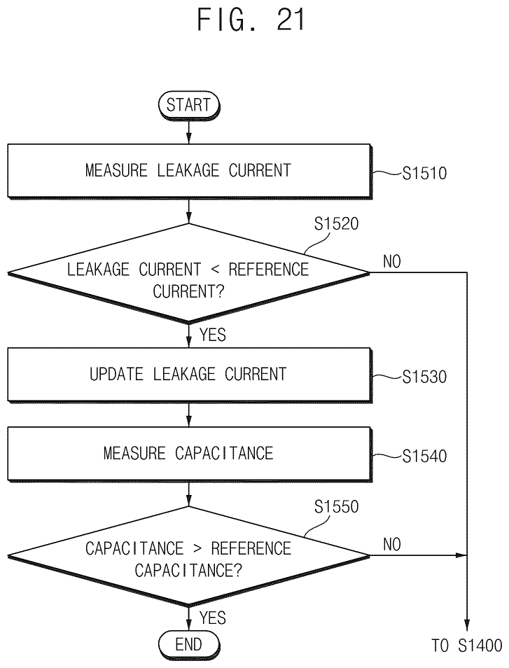

FIG. 21 is a flowchart illustrating an example of checking an initial state of a secondary power source, e.g., operation S1500 of FIG. 20.

Referring to FIGS. 20 and 21, operations S1510, S1520, S1530, S1540 and S1550 may be substantially the same as operations S1240, S1330, S1250, S1220 and S1310 in FIG. 18, respectively. In this case, when operation S1220 is initially performed, the leakage current measured in S1510 and stored in S1530 may be used.

FIGS. 22A, 22B, 23A and 23B are diagrams illustrating examples of configurations and operations of storage devices according to various implementations.

Referring to FIG. 22A, a storage device may include a power-loss protection (PLP) IC 600a and a controller IC 700a. The PLP IC 600a may include the secondary power source 110, the charging circuit 120 and the monitoring circuit 130. The controller IC 700a may include the storage controller 310. One IC may represent an individual chip or package. FIG. 22A illustrates an example in which the secondary power source 110, the charging circuit 120 and the monitoring circuit 130 are included in the same chip.

Referring to FIG. 22B, a storage device may include a PLP IC 600b and a controller IC 700b. The PLP IC 600b may include the secondary power source 110, the charging circuit 120, the first path 140 and the second path 150. The controller IC 700b may include the control circuit 160 and the storage controller 310. FIG. 22B illustrates an example in which a part (e.g., the control circuit 160) of the monitoring circuit 130 is included in a chip different from a chip including the secondary power source 110 and the charging circuit 120.

Referring to FIG. 23A, when the external power supply voltage VEXT is normally supplied to a storage device, power PWR_VEXT that is generated based on the external power supply voltage VEXT may be supplied to the storage controller 310, the nonvolatile memory 320 and the buffer memory 330 through a PLP IC 600 and a power management integrated circuit (PMIC) 900. For example, the main system 300 may operate based on the external power supply voltage VEXT.

Referring to FIG. 23B, when the external power supply voltage VEXT is blocked or cut off (e.g., when a sudden power-off (SPO) event occurs), the secondary power source 110 may generate the internal power supply voltage VINT, and power PWR_VINT that is generated based on the internal power supply voltage VINT may be supplied to the storage controller 310, the nonvolatile memory 320 and the buffer memory 330 through the PLP IC 600 and the PMIC 900. For example, the main system 300 may operate based on the internal power supply voltage VINT.

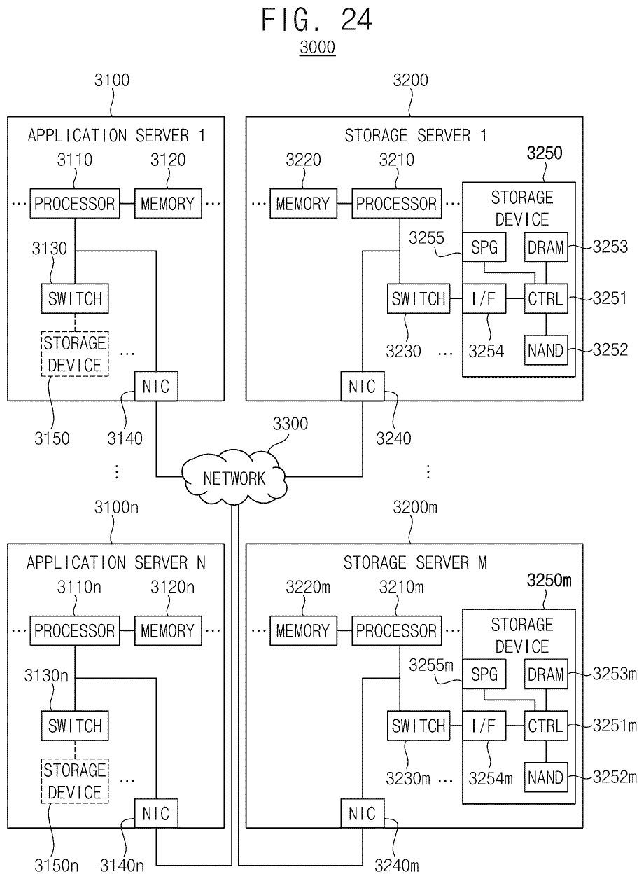

FIG. 24 is a block diagram illustrating a data center including a storage device according to some implementations

Referring to FIG. 24, a data center 3000 may be a facility that collects various types of data and provides various services, and may be referred to as a data storage center. The data center 3000 may be a system for operating search engines and databases, and may be a computing system used by companies such as banks or government agencies. The data center 3000 may include application servers 3100 to 3100n and storage servers 3200 to 3200m. The number of the application servers 3100 to 3100n and the number of the storage servers 3200 to 3200m may vary in various implementations, and the number of the application servers 3100 to 3100n and the number of the storage servers 3200 to 3200m may be different from each other.

The application server 3100 may include at least one processor 3110 and at least one memory 3120, and the storage server 3200 may include at least one processor 3210 and at least one memory 3220. An operation of the storage server 3200 will be described as an example. The processor 3210 may control overall operations of the storage server 3200, and may access the memory 3220 to execute instructions and/or data loaded in the memory 3220. The memory 3220 may include at least one of a double data rate (DDR) synchronous dynamic random access memory (SDRAM), a high bandwidth memory (HBM), a hybrid memory cube (HMC), a dual in-line memory module (DIMM), an Optane DIMM, a nonvolatile DIMM (NVDIMM), etc. The number of the processors 3210 and the number of the memories 3220 included in the storage server 3200 may vary in various implementations. In some implementations, the processor 3210 and the memory 3220 provides a processor-memory pair. In some implementations, the number of the processors 3210 and the number of the memories 3220 are different from each other. The processor 3210 may include a single core processor or a multiple core processor. The above description of the storage server 3200 may be similarly applied to the application server 3100. The application server 3100 may include at least one storage device 3150, and the storage server 3200 may include at least one storage device 3250. In some implementations, the application server 3100 does not include the storage device 3150. The number of the storage devices 3250 included in the storage server 3200 may vary in various implementations.

The application servers 3100 to 3100n and the storage servers 3200 to 3200m may communicate with each other through a network 3300. The network 3300 may be implemented using a fiber channel (FC) or an Ethernet. The FC may be a medium used for a relatively high speed data transmission, and an optical switch that provides high performance and/or high availability may be used. The storage servers 3200 to 3200m may be provided as file storages, block storages or object storages according to an access scheme of the network 3300.

In some implementations, the network 3300 is a storage-only network or a network dedicated to a storage such as a storage area network (SAN). For example, the SAN may be an FC-SAN that uses an FC network and is implemented according to an FC protocol (FCP). For another example, the SAN may be an IP-SAN that uses a transmission control protocol/internet protocol (TCP/IP) network and is implemented according to an iSCSI (a SCSI over TCP/IP or an Internet SCSI) protocol. In some implementations, the network 3300 is a general or normal network such as the TCP/IP network. For example, the network 3300 may be implemented according to at least one of protocols such as an FC over Ethernet (FCOE), a network attached storage (NAS), a nonvolatile memory express (NVMe) over Fabrics (NVMe-oF), etc.

Hereinafter, examples will be described with respect to the application server 3100 and the storage server 3200. The description of the application server 3100 may be applied to the other application server 3100n, and the description of the storage server 3200 may be applied to the other storage server 3200m.

The application server 3100 may store data requested to be stored by a user or a client into one of the storage servers 3200 to 3200m through the network 3300. In addition, the application server 3100 may obtain data requested to be read by the user or the client from one of the storage servers 3200 to 3200m through the network 3300. For example, the application server 3100 may be implemented as a web server or a database management system (DBMS).

The application server 3100 may access a memory 3120n or a storage device 3150n included in the other application server 3100n through the network 3300, and/or may access the memories 3220 to 3220m or the storage devices 3250 to 3250m included in the storage servers 3200 to 3200m through the network 3300. Thus, the application server 3100 may perform various operations on data stored in the application servers 3100 to 3100n and/or the storage servers 3200 to 3200m. For example, the application server 3100 may execute a command for moving or copying data between the application servers 3100 to 3100n and/or the storage servers 3200 to 3200m. The data may be transferred from the storage devices 3250 to 3250m of the storage servers 3200 to 3200m to the memories 3120 to 3120n of the application servers 3100 to 3100n directly or through the memories 3220 to 3220m of the storage servers 3200 to 3200m. For example, the data transferred through the network 3300 may be encrypted data for security or privacy.

In the storage server 3200, an interface 3254 may provide a physical connection between the processor 3210 and a controller 3251 and/or a physical connection between a network interface card (NIC) 3240 and the controller 3251. For example, the interface 3254 may be implemented based on a direct attached storage (DAS) scheme in which the storage device 3250 is directly connected with a dedicated cable. For example, the interface 3254 may be implemented based on at least one of various interface schemes such as an advanced technology attachment (ATA), a serial ATA (SATA) an external SATA (e-SATA), a small computer system interface (SCSI), a serial attached SCSI (SAS), a peripheral component interconnection (PCI), a PCI express (PCIe), an NVMe, an IEEE 1394, a universal serial bus (USB), a secure digital (SD) card interface, a multi-media card (MMC) interface, an embedded MMC (eMMC) interface, a universal flash storage (UFS) interface, an embedded UFS (eUFS) interface, a compact flash (CF) card interface, etc.

The storage server 3200 may further include a switch 3230 and the NIC 3240. The switch 3230 may selectively connect the processor 3210 with the storage device 3250 or may selectively connect the NIC 3240 with the storage device 3250 under a control of the processor 3210. Similarly, the application server 3100 may further include a switch 3130 and an NIC 3140.

In some implementations, the NIC 3240 includes a network interface card, a network adapter, or the like. The NIC 3240 may be connected to the network 3300 through a wired interface, a wireless interface, a Bluetooth interface, an optical interface, or the like. The NIC 3240 may further include an internal memory, a digital signal processor (DSP), a host bus interface, or the like, and may be connected to the processor 3210 and/or the switch 3230 through the host bus interface. The host bus interface may be implemented as one of the above-described examples of the interface 3254. In some implementations, the NIC 3240 is integrated with at least one of the processor 3210, the switch 3230 and the storage device 3250.

In the storage servers 3200 to 3200m and/or the application servers 3100 to 3100n, the processor may transmit a command to the storage devices 3150 to 3150n and 3250 to 3250m or the memories 3120 to 3120n and 3220 to 3220m to program or read data. For example, the data may be error-corrected data by an error correction code (ECC) engine. For example, the data may be processed by a data bus inversion (DBI) or a data masking (DM), and may include a cyclic redundancy code (CRC) information. For example, the data may be encrypted data for security or privacy.

The storage devices 3150 to 3150m and 3250 to 3250m may transmit a control signal and command/address signals to NAND flash memory devices 3252 to 3252m in response to a read command received from the processor. When data is read from the NAND flash memory devices 3252 to 3252m, a read enable (RE) signal may be input as a data output control signal and may serve to output data to a DQ bus. A data strobe signal (DQS) may be generated using the RE signal. The command and address signals may be latched in a page buffer based on a rising edge or a falling edge of a write enable (WE) signal.

The controller 3251 may control overall operations of the storage device 3250. In some implementations, the controller 3251 includes a static random access memory (SRAM). The controller 3251 may write data into the NAND flash memory device 3252 in response to a write command, or may read data from the NAND flash memory device 3252 in response to a read command. For example, the write command and/or the read command may be provided from the processor 3210 in the storage server 3200, the processor 3210m in the other storage server 3200m, or the processors 3110 to 3110n in the application servers 3100 to 3100n. A DRAM 3253 may temporarily store (e.g., may buffer) data to be written to the NAND flash memory device 3252 or data read from the NAND flash memory device 3252. Further, the DRAM 3253 may store meta data. The meta data may be data generated by the controller 3251 to manage user data or the NAND flash memory device 3252.

The storage device 3250 may be any of the storage devices described with respect to FIGS. 1 to 23B, e.g., may include the monitoring circuit 130 in FIG. 1, and may perform the above-described methods of monitoring the secondary power source.

The above-described examples (e.g., examples of storage devices and processes associated with secondary power sources) may be applied to various electronic devices and systems that include the storage devices. For example, the examples may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automobile, etc.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of various examples and is not to be construed as being limited to those examples. Although some examples have been described, those skilled in the art will readily appreciate that many modifications are possible without departing from the scope of this disclosure. Accordingly, all such modifications are intended to be included within the scope of this disclosure.

What is claimed is:

1. A storage device comprising:
a secondary power source including at least one capacitor, the secondary power source configured to be charged based on a charging voltage and to generate an internal power supply voltage;
a charging circuit configured to generate the charging voltage based on an external power supply voltage;
a main system configured to operate based on the external power supply voltage and the internal power supply voltage; and
a monitoring circuit connected to the secondary power source, the monitoring circuit configured to detect whether the secondary power source is defective by measuring a capacitance of the at least one capacitor and a leakage current of the at least one capacitor,
wherein the monitoring circuit includes:
a first path separate from a leakage path of the at least one capacitor, the leakage current flowing through the leakage path;
a second path separate from the leakage path and the first path; and
a control circuit configured to:
control activation and deactivation of the second path,
calculate the leakage current based on behavior of the monitoring circuit while the second path is activated and on behavior of the monitoring circuit while the second path is deactivated,
calculate the capacitance based on the leakage current, and
determine whether the secondary power source is defective based on at least one of the leakage current or the capacitance.

2. The storage device of claim 1,
wherein the first path includes a first resistor that is connected between the charging voltage and a ground voltage, and
wherein the second path includes a second resistor and a leakage switch that are connected in series between the charging voltage and the ground voltage.

3. The storage device of claim 2,
wherein the charging circuit is configured such that, based on the charging voltage, a capacitor voltage of the at least one capacitor repeatedly increases and decreases between a first voltage level and a second voltage level lower than the first voltage level, and
wherein the control circuit is configured to:
measure a first time interval during which the capacitor voltage decreases from the first voltage level to the second voltage level while the leakage switch is turned off to deactivate the second path;
measure a second time interval during which the capacitor voltage decreases from the first voltage level to the second voltage level while the leakage switch is turned on to activate the second path; and
calculate the leakage current based on the first time interval and the second time interval.

4. The storage device of claim 3, wherein the monitoring circuit is configured to calculate the leakage current based on a predetermined relationship between the leakage current, a current in the first path, a current in the second path, the first time interval, and the second time interval.

5. The storage device of claim 4, wherein the monitoring circuit is configured to calculate the capacitance based on a predetermined relationship between the capacitance, the current in the first path, the leakage current, the first time interval, the first voltage level, and the second voltage level.

6. The storage device of claim 3, wherein the charging circuit includes:
a voltage regulator configured to generate the charging voltage; and
a voltage detector configured to control an operation of the voltage regulator such that supply of the charging voltage is stopped when the capacitor voltage is higher than the first voltage level and the charging voltage is supplied when the capacitor voltage is lower than the second voltage level.

7. The storage device of claim 3, wherein the second time interval is shorter than the first time interval.

8. The storage device of claim 1,
wherein the control circuit is configured to perform a first monitoring operation and a second monitoring operation,
wherein, in the first monitoring operation, the control circuit determines based on the capacitance whether the secondary power source is defective, and
wherein, in the second monitoring operation, the control circuit determines based on the leakage current whether the secondary power source is defective.

9. The storage device of claim 8, wherein the control circuit is configured to perform the first monitoring operation more often than the second monitoring operation.

10. The storage device of claim 9, wherein the control circuit is configured to repeatedly perform the first monitoring operation, and
wherein the control circuit is configured to perform the second monitoring operation based on having performed the first monitoring operation a number of times that is greater than or equal to a reference number of times.

11. The storage device of claim 8, wherein the control circuit is configured to perform the first monitoring operation periodically with a first frequency and the second monitoring operation periodically with a second frequency,
wherein the first frequency is greater than the second frequency.

12. The storage device of claim 8, wherein the control circuit is configured to check an initial state of the secondary power source at an initial operating time by performing the second monitoring operation once and then by performing the first monitoring operation.

13. The storage device of claim 1,
wherein the control circuit is configured to determine that the secondary power source is defective based on the leakage current being greater than or equal to a reference current, and
wherein the control circuit is configured to determine that the secondary power source is defective based on the capacitance being less than or equal to a reference capacitance.

14. The storage device of claim 13, wherein, based on determining that the secondary power source is defective, the storage device is configured to stop an operation of the storage device.

15. The storage device of claim 1, wherein the secondary power source, the charging circuit, and the monitoring circuit are included in one integrated circuit.

16. The storage device of claim 1, wherein at least a part of the monitoring circuit is included in an integrated circuit separate from an integrated circuit that includes the secondary power source and the charging circuit.

17. A method of monitoring a secondary power source included in a storage device,
wherein the secondary power source includes at least one capacitor and is configured to generate an internal power supply voltage based on a charging voltage, and
wherein the method comprises:
measuring a leakage current of the at least one capacitor using a monitoring circuit connected to the secondary power source;
measuring a capacitance of the at least one capacitor using the monitoring circuit and based on the leakage current; and
determining whether the secondary power source is defective based on at least one of the leakage current or the capacitance,
wherein the monitoring circuit includes:
a first path separate from a leakage path of the at least one capacitor, the leakage current flowing through the leakage path; and
a second path separate from the leakage path and the first path, and
wherein the leakage current is calculated based on behavior of the monitoring circuit while the second path is activated and behavior of the monitoring circuit while the second path is deactivated.

18. The method of claim 17, wherein measuring the leakage current comprises:
measuring a first time interval during which a capacitor voltage of the at least one capacitor decreases from a first voltage level to a second voltage level lower than the first voltage level while the second path is deactivated;
measuring a second time interval during which the capacitor voltage decreases from the first voltage level to the second voltage level while the second path is activated; and
calculating the leakage current based on the first time interval and the second time interval.

19. The method of claim 17, comprising, during a predetermined time interval, measuring the capacitance periodically with a first frequency and a first number of times, and
during the predetermined time interval, measuring the leakage current periodically with a second frequency and a second number of times,
wherein the first frequency is greater than the second frequency and the second number of times is less than the first number of times.

20. A storage device comprising:
a secondary power source configured to generate an internal power supply voltage based on a charging voltage, the secondary power source including:
a capacitor connected between the charging voltage and a ground voltage, and
a leakage path through which a leakage current of the capacitor flows;
a charging circuit configured to generate the charging voltage based on an external power supply voltage;
a main system configured to operate based on the external power supply voltage and the internal power supply voltage; and
a monitoring circuit connected to the secondary power source, the monitoring circuit configured to detect whether the secondary power source is defective by measuring a capacitance of the capacitor and the leakage current of the capacitor,
wherein the monitoring circuit includes:
a first path including a first resistor that is connected between the charging voltage and the ground voltage;
a second path including a second resistor and a leakage switch that are connected in series between the charging voltage and the ground voltage;
a measurer configured to:
measure a first time interval during which a capacitor voltage of the capacitor decreases from a first voltage level to a second voltage level lower than the first voltage level while the leakage switch is turned off to deactivate the second path, and
measure a second time interval during which the capacitor voltage decreases from the first voltage level to the second voltage level while the leakage switch is turned on to activate the second path;
a calculator configured to:
calculate the leakage current based on the first time interval and the second time interval, and
calculate the capacitance based on the leakage current; and
a determinator configured to determine that the secondary power source is defective based on the leakage current being greater than or equal to a reference current, and to determine that the secondary power source is defective based on the capacitance being less than or equal to a reference capacitance.
